(19) United States
(12) Patent Application Publication
(10) Pub. No.: US 2003/0087515 A1
(43) Pub. Date: May 8, 2003

(54) Method for fabricating semiconductor device

(75) Inventor: Shinobu Shigeta, Tateyama City (JP)

Correspondence Address: CROWELL & MORING LLP, INTELLECTUAL PROPERTY GROUP, P.O. BOX 14300, WASHINGTON, DC, 20044-4300, US

(73) Assignee: UMC Japan, Tateyama City (JP)

(21) Appl. No.: 10/281,984

(22) Filed: Oct. 29, 2002

(30) Foreign Application Priority Data
Nov. 8, 2001 (JP) 342867/2001

(51) Int. Cl. H01L 21/4763; H01L 21/44

(52) U.S. Cl. 438/633; 438/687

(57) ABSTRACT

A method for fabricating a semiconductor device in which a wiring having a thickness with a high uniformity can be formed in the process of wiring formation using a dual damascene technology. In the method, an insulating film being patterned is formed on a semiconductor wafer, followed by forming a Cu film on both a wiring formation area which the insulating film is not formed and said insulating film. Then, the Cu film is mechanically polished until a step caused by a wiring layout is disappeared. After that, the Cu film on the insulating film is polished using chemical and mechanical polishing procedures to form a wiring made of the Cu film in the wiring formation area.

### BACKGROUND OF THE INVENTION

1. Field of the Invention

The present invention relates to a method for fabricating a semiconductor device in which a metal wiring is formed on a semiconductor wafer using a dual damascene technology.

2. Description of the Prior Art

Heretofore, a dual damascene technology has been used in a method for fabricating a semiconductor device in which a copper (Cu) wiring is formed on a semiconductor wafer. Such a dual damascene technology may include the following steps. That is, at first, an insulating film is formed on the surface of a semiconductor wafer, and a resist is then applied on the insulating film. Subsequently, a predetermined wiring pattern is transferred on the resist using an exposure apparatus, and part of the insulating film formed on the area corresponding to the wiring pattern is then removed using an etching apparatus. As a result, a grooved portion corresponding to the wiring pattern (a portion for wiring formation) is formed. After that, a copper (Cu) film is formed over the surface of the semiconductor wafer, followed by a chemical mechanical polishing (CMP) treatment to remove part of the Cu film on the insulating film. Here, the CMP treatment is a technology using both chemical and mechanical reactions. That is, the chemical reaction is performed between a slurry solution and a target material, while the mechanical reaction (i.e., friction) is performed between the target material and abrasive particles with a particle size of around several-tenths micrometers to several micrometers. Consequently, the Cu lines are formed along the wiring pattern in a wiring-formation area on the semiconductor wafer.

In the dual damascene technology, a hollow region (step) is unwillingly formed on the Cu film depending on the wiring pattern when the Cu film is formed over the surface of the semiconductor wafer. In other words, the surface of the Cu film, which corresponds to the wiring formation area, is recessed under the influence of a high aspect ratio of the insulating film. If the Cu film is subjected to the CMP treatment under such a condition, the slurry solution is introduced into the recessed portion of the Cu film, so that the whole surface of the Cu film can be evenly polished. Therefore, the surface of the Cu wiring formed in the wiring formation area is also recessed.

Referring now to FIG. 2, there is shown a schematic diagram as a combination of a plan view and a cross sectional view along the line A-A′ of the plan view for illustrating Cu wirings formed by the conventional dual damascene technology. As shown in the figure, the thickness of each of the Cu lines varies widely. That is, there is a thin portion in the Cu line. If a comparatively wide Cu wiring pattern or the like is to be formed, the middle portion of the Cu line is thinned. In this case, there is apprehension that the resistance of each electric line may be affected. Accordingly, in the prior art, it is difficult to provide the Cu line with a high uniformity of its thickness when the CMP treatment is performed under the condition in which there is a recessed region in the ground surface.

### SUMMARY OF THE INVENTION

The present invention has been completed in view of the above circumstances. It is an object of the present invention is to provide a method for fabricating a semiconductor device in which an electric line with a high uniformity of its thickness can be provided in the process for wiring formation using a dual damascene technology.

For attaining the above object, there is provided a method for fabricating a semiconductor device in which a metal wiring is formed on the surface of a semiconductor wafer, comprising the steps of: forming an insulating film being patterned on a semiconductor wafer; forming a metal film on a wiring formation area which the insulating film is not formed and said insulating film; mechanically polishing the metal film using a grinder on which abrasive particles with a predetermined hardness are fixed until a step caused by a wiring layout and formed on the surface of the metal film is disappeared; and forming a wiring made of the metal film in the wiring formation area by polishing the metal surface on the insulating film using chemical and mechanical polishing procedures after the previous mechanical polishing.

Here, in this method, the metal film may be made of copper (Cu).

### BRIEF DESCRIPTION OF THE DRAWINGS

FIG. 1 is a schematic diagram for illustrating a method for fabricating a semiconductor device as one of preferred embodiments of the present invention, where each of (a) to (d) corresponds to each step of the method; and

FIG. 2 is a schematic diagram as a combination of a plan view and a cross sectional view along the wiring A-A′ of the plan view for illustrating Cu lines formed by the conventional dual damascene technology.

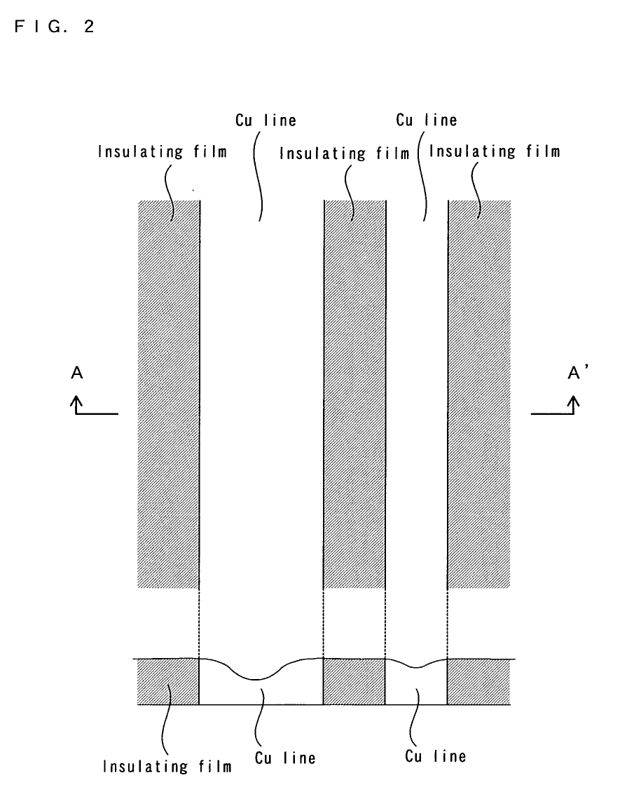

### DETAILED DESCRIPTION OF THE PREFERRED EMBODIMENTS

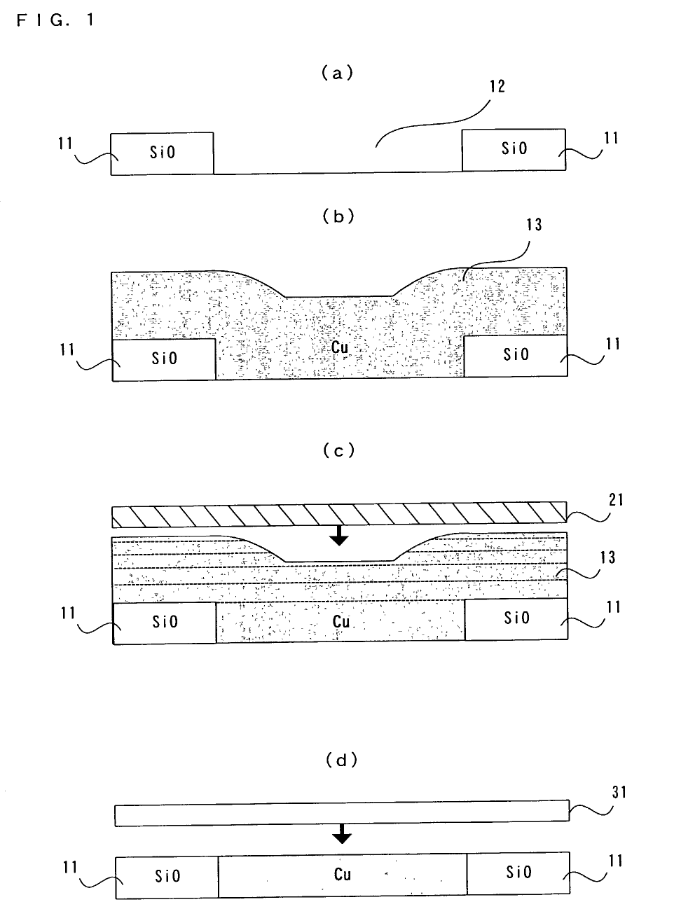

Hereinafter, one of preferred embodiments of the present invention will be described with reference to the attached drawing. Referring to FIG. 1, there is illustrated a method for fabricating a semiconductor device as one of preferred embodiments of the present invention.

The method for fabricating the semiconductor device of the present embodiment includes the process for forming a metal wiring on a semiconductor wafer using a dual damascene technology. Here, we will consider the formation of Cu wirings in a multi-layered structure. Here, furthermore, the term “dual damascene technology” refers to a technology for forming an insulating layer being patterned on a semiconductor wafer, followed by forming a metal wiring thereon.

Next, we will describe the method for fabricating the semiconductor device of the present embodiment. At first, an insulating film (SiO film) is formed on a semiconductor wafer. Subsequently, a resist is applied on the insulating film and a predetermined wiring pattern is then transferred on the resist by an exposure apparatus. Furthermore, part of the insulating film formed on an area corresponding to the wiring pattern is removed using an etching apparatus. As a result, a patterned insulating film 11 on the semiconductor wafer is obtained as shown in FIG. 1(a). On the other hand, other area on which such an insulating film 11 is not formed is provided as a wiring formation area 12 on which a wiring is to be formed by the step described later.

Next, as shown in FIG. 1(b), the Cu film (metal film) 13 is formed over the surface of the semiconductor wafer. That is, the Cu film 13 is formed on both the insulating film 11 and the wiring formation area 12. At this time, due to a wiring layout, a step is caused on the surface of the Cu film 13. In other words, by the influence of a high aspect ratio of the insulating film 11, there is a recessed portion on the surface of the Cu film 13 formed on the area corresponding to the wiring formation area 12.

Furthermore, as shown in FIG. 1(c), the Cu film 13 is subjected to a mechanical polishing. In the mechanical polishing, a grinder 21 having a surface on which abrasive particles of predetermined hardness are fixed is used. The abrasive particles may be diamond particles or the like. In addition, the grinder 21 may be one on which a polishing cloth is mounted. Thus, the Cu film 13 can be mechanically polished by the abrasive particles when the grinder 21 touches on the surface of the Cu film 13 during the rotation of the grinder 21. Such a mechanical polishing is performed until the step caused on the surface of the Cu film 13 due to the wiring layout is disappeared. In other words, the surface of Cu film 13 can be almost flattened by the mechanical polishing.

If the above mechanical polishing is performed, however, many scars due to the abrasive particles persist on the surface of the Cu film 13. That is, micro-scratches are generated on that surface. Therefore, in the next step as shown in FIG. 1(d), a CMP treatment is performed for removing the Cu film 13 from the insulating film 11 and also for keeping the surface of the Cu film 13 in trim.

Next, we will describe the CMP treatment in detail. Here, for actually performing the CMP treatment, in contrast to the positioning relationship shown in FIG. 1(d), the semiconductor wafer is positioned above the grinder 31. At first, slurry is applied on the surface of the grinder 31. Here, the term “slurry” refers to a weak alkaline solution in which a plurality of colloidal silica particles (abrasive particles) with 0.1 micrometers in diameter. Also, the grinder 31 to be used in the CMP treatment is different from the grinder 21 to be used in the mechanical polishing treatment. That is, there are many recessed portions formed on the surface of the grinder 31. Therefore, when the grinder 31 rotates, the abrasive particles can be rotated together while they are being stocked in the recessed portions formed on the surface of the grinder 31.

While rotating the grinder 31, the grinder 31 touches the surface of the Cu film 13. As a result, the Cu film 13 can be polished by two reactions. That is, an abrasion reaction is performed between the abrasive particles and the target material and also a chemical reaction is performed between the slurry solution and the target material. In the CMP treatment, the Cu film 13 is polished using the chemical treatment to remove the micro-scratches generated on the surface of the Cu film 13. Thus, the surface of the Cu film 13 can be finished in trim. Furthermore, in the present embodiment, the surface of the Cu film 13 can be almost evenly formed by means of a mechanical polishing. The surface of the Cu wiring can be also almost evenly formed by the formation of the Cu wiring in the wiring formation area 12 by the CMP treatment.

Consequently, a first wiring layer is formed. Then, an inter-layer insulating film is formed on the first wiring layer. Subsequently, a second wiring layer is formed by the same process as one described above. Repeating the above process, furthermore, the multi-layer of wirings can be formed.

Therefore, according to the method for fabricating the semiconductor device in accordance with the above embodiment, in the process of forming a Cu wiring on a semiconductor wafer using the dual damascene technology, a Cu film is mechanically polished until the step caused on the surface of the Cu film due to the wiring layout is disappeared by means of a grinder on which abrasive particles with a predetermined hardness. Thus, the surface of the Cu film becomes almost flat. After the mechanical polishing, therefore, the Cu film on the insulating film is polished by means of the CMP treatment. As a result, the Cu wiring having a uniform thickness is obtained. In addition, the resulting Cu wiring has a surface being kept in trim.

Furthermore, the present invention is not limited to the above embodiment. Various modifications can be allowed within the gist of the present invention.

The above present invention has been described in the case of using Cu as a material of the metal film. According to the present invention, alternatively, any material such as aluminum or gold may be used.

Therefore, according to the method for fabricating the semiconductor device in accordance with the present invention, in the process of forming a metal wiring on a semiconductor wafer using the dual damascene technology, a metal film is mechanically polished until the step caused on the surface of the metal film due to the wiring layout is disappeared by means of a grinder on which abrasive particles with a predetermined hardness. Thus, the surface of the metal film becomes almost flat. After the mechanical polishing, therefore, the metal film on the insulating film is polished by means of the CMP treatment. As a result, the Cu wiring having a uniform thickness can be obtained. In addition, the resulting metal wiring has a surface being kept in trim.

What is claimed is:

1. A method for fabricating a semiconductor device in which a metal wiring is formed on the surface of a semiconductor wafer, comprising the steps of:
forming an insulating film being patterned on a semiconductor wafer;
forming a metal film on both a wiring formation area which the insulating film is not formed and said insulating film;
mechanically polishing the metal film using a grinder on which abrasive particles with a predetermined hardness are fixed until a step caused by a wiring layout and formed on the surface of the metal film is disappeared; and
forming a wiring made of the metal film in the wiring formation area by polishing the metal surface on the insulating film using chemical and mechanical polishing procedures after the previous mechanical polishing.

2. A method for fabricating a semiconductor device as claimed in claim 1, wherein
the metal film is made of copper.
